(19) United States
(12) Patent Application Publication
(10) Pub. No.: US 2018/0291507 A1
(43) Pub. Date: Oct. 11, 2018

(54) VAPOR PHASE GROWTH APPARATUS AND ABNORMALITY DETECTION METHOD

(71) Applicant: NuFlare Technology, Inc., Kanagawa (JP)

(72) Inventors: Takanori HAYANO, Yokohama Kanagawa (JP); Hideki ITO, Yokohama Kanagawa (JP); Tatsuhiko IIJIMA, Numazu Shizuoka (JP)

(21) Appl. No.: 15/946,696

(22) Filed: Apr. 5, 2018

Related U.S. Application Data
(63) Continuation of application No. PCT/JP2016/079070, filed on Sep. 30, 2016.

(30) Foreign Application Priority Data
Oct. 8, 2015 (JP) 2015-200348

(51) Int. Cl. C23C 16/46; C30B 25/10; C23C 16/458; H01L 21/67

(52) U.S. Cl. CPC C23C 16/46; H01L 21/67248; C23C 16/4586; C30B 25/10

(57) ABSTRACT

A vapor phase growth apparatus has a reaction chamber to form a film on an upper surface of a substrate by a vapor growth reaction, a gas supplier to supply a gas to the reaction chamber, a heater to heat the substrate from a back side of the substrate, and a controller to control an output of the heater. The controller has an electrical characteristics measuring instrument which measures electrical characteristics of the heater at predetermined time intervals and detects a variation value of the electrical characteristics between a newly value and previous value, and a threshold determiner which extracts a maximum value and a minimum value of a predetermined number of detected variation values and newly variation value of the electrical characteristics, calculates differences between the maximum value and the minimum value at the predetermined time intervals, and determines whether the difference exceeds a predetermined threshold.

### CROSS REFERENCE TO RELATED APPLICATIONS

This application is based upon and claims the benefit of priority from the prior Japanese Patent Application No. 2015-200348, filed on Oct. 8, 2015, the entire contents of which are incorporated herein by reference.

### FIELD

Embodiments of the present invention relate to a vapor phase growth apparatus including a heater and an abnormality detection method of the heater.

### BACKGROUND

An epitaxial growth technique for growing a single crystal thin film on a single crystal substrate such as a silicon substrate is used for manufacturing a Light Emitting Diode (LED) or an electronic device using a compound semiconductor such as GaN and SiC.

In a vapor phase growth apparatus used for the epitaxial growth technique, a wafer is placed in a reaction chamber of which a pressure is maintained to be a normal pressure or a reduced pressure. Then, when a gas to be a material to form a film is supplied to the reaction chamber while the wafer is heated, thermal decomposition reaction and hydrogen reduction reaction of the source gas occur on the surface of the wafer, and an epitaxial film is formed on the wafer. Each film to be formed on the wafer has difference conditions required to form the film, such as the temperature and the source gas. Therefore, it is necessary to control a temperature of a heater (heater) for heating the wafer and a kind and a flow rate of the gas to be supplied to the reaction chamber (refer to JP 2009-245978 A).

However, the heater is broken due to long time use. When the heater is broken in the reaction chamber, components of the heater scatter and cause contamination of the reaction chamber. In a case where the heater is broken in the reaction chamber, not only a wafer in the reaction chamber becomes a defective, but also it is necessary to clean the inside of the reaction chamber. Therefore, it takes time and effort to restore the vapor phase growth apparatus.

The present invention provides a vapor phase growth apparatus and an abnormality detection method which can accurately predict a timing of breakage of a heater before the heater is completely broken.

### BRIEF DESCRIPTION OF THE DRAWINGS

FIG. 1 is a view illustrating a schematic configuration of a vapor phase growth apparatus according to an embodiment.

FIG. 2 is a block diagram illustrating an exemplary internal configuration of a heater driving unit.

FIG. 3 is a graph illustrating electrical characteristics of each heater in each of four vapor phase growth apparatuses.

FIG. 4 is a block diagram illustrating an exemplary internal configuration of a controller.

FIG. 5 is a flowchart illustrating an exemplary processing operation of the controller.

FIG. 6 is a graph illustrating a difference between a maximum value and a minimum value of a resistance value difference with respect to time.

FIG. 7 is a graph illustrating an exemplary calculation result of resistance value differences which have been calculated for the past four times and calculated this time.

FIG. 8 is a flowchart illustrating an internal configuration of a controller according to a second embodiment.

FIG. 9 is a flowchart illustrating an exemplary processing operation of the controller.

### DETAILED DESCRIPTION

According to the present embodiment, a vapor phase growth apparatus has a reaction chamber to form a film on an upper surface of a substrate by a vapor growth reaction, a gas supplier to supply a gas to the reaction chamber, a heater to heat the substrate from a back side of the substrate and a controller to control an output of the heater. The controller has an electrical characteristics measuring instrument which measures electrical characteristics of the heater at predetermined time intervals and detects a variation value of the electrical characteristics between a newly value and previous value, and a threshold determiner which extracts a maximum value and a minimum value of a predetermined number of detected variation values and newly variation value of the electrical characteristics, calculates differences between the maximum value and the minimum value at the predetermined time intervals, and determines whether the difference exceeds a predetermined threshold.

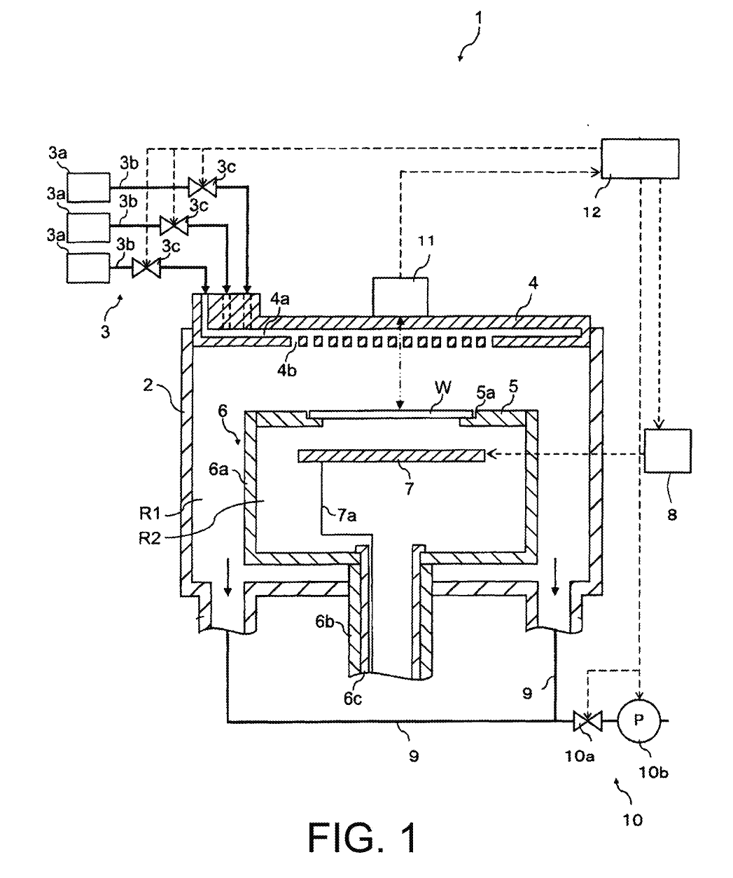

Embodiments of the present invention will be described below with reference to the drawings. FIG. 1 is a view illustrating a schematic configuration of a vapor phase growth apparatus 1 according to an embodiment. In the present embodiment, an example will be described in which a silicon substrate, more specifically, a silicon wafer (simply referred to as wafer below) W is used as a substrate on which film formation processing is performed and a plurality of films is laminated on the wafer W.

The vapor phase growth apparatus 1 in FIG. 1 includes a chamber 2 in which the films are formed on the wafer W, a gas supply unit 3 which supplies a source gas to the wafer W in the chamber 2, a raw material discharge unit 4 which is positioned in an upper portion of the chamber 2, a susceptor 5 which supports the wafer W in the chamber 2, a rotation unit 6 which holds and rotates the susceptor 5, a heater 7 which heats the wafer W, a heater driving unit 8 which drives the heater 7, a gas discharge unit 9 which discharges gas in the chamber 2, an exhaust mechanism 10 which exhausts the gas from the gas discharge unit 9, a radiation thermometer 11 which measures a temperature of the wafer W, and a controller 12 which controls the units.

The chamber 2 has a shape (for example, a cylindrical shape) capable of storing the wafer W on which the films will be formed, and the susceptor 5, the heater 7, a part of the rotation unit 6, and the like are housed in the chamber 2.

The gas supply unit 3 includes a plurality of gas storage units 3a which individually and respectively stores a plurality of kinds of gases, a plurality of gas pipes 3b which connects the respective gas storage units 3a to the raw material discharge unit 4, and a plurality of gas valves 3c which adjusts a flow rate of the gas flowing through the gas pipe 3b. Each gas valve 3c is connected to the corresponding gas pipe 3b. The controller 12 controls the plurality of gas valves 3c. In actual pipe arrangement, a plurality of kinds of configuration can be used, for example, the gas pipes are coupled, a single gas pipe is branched into a plurality of gas pipes, or a branch and coupling of the gas pipes are combined.

The source gas supplied from the gas supply unit 3 passes through the raw material discharge unit 4 and is discharged into the chamber 2. The source gas (process gas) discharged into the chamber 2 is supplied on the wafer W, and accordingly, a desired film is formed on the wafer W. The kind of the source gas to be used is not particularly limited. Depending on the kind of the film to be formed, the source gas can be variously changed.

A shower plate 4a is provided on the bottom surface side of the raw material discharge unit 4. The shower plate 4a can be made of a metal material such as stainless steel and aluminum alloy. The gases from the plurality of gas pipes 3b are mixed in the raw material discharge unit 4 and supplied into the chamber 2 through gas ejection ports 4b of the shower plate 4a. Alternatively, it is possible that a plurality of gas flow paths is provided in the shower plate 4a and the plurality of kinds of gases are supplied to the wafer W in the chamber 2 while being separated.

The structure of the raw material discharge unit 4 should be selected in consideration of uniformity, a raw material efficiency, reproducibility, a manufacturing cost, and the like of the formed film. However, if these requirements are satisfied, the structure is not particularly limited, and a known structure can be appropriately used.

The susceptor 5 is provided at the upper portion of the rotation unit 6 and has a structure for supporting the wafer W in a state of placing the wafer W on a hole provided on the inner peripheral side of the susceptor 5. In the example in FIG. 1, the susceptor 5 has an annular shape having an opening at the center of the susceptor 5. However, the shape of the susceptor 5 may be a substantially flat plate shape with no opening.

The heater 7 is a heating unit for heating the susceptor 5 and/or the wafer W. If requirements such as an ability to heat an object to be heated to a desired temperature and with a desired temperature distribution, durability, and the like are satisfied, the kind of the heater 7 is not particularly limited. Specifically, resistance heating, lamp heating, induction heating, and the like can be exemplified.

The heater driving unit 8 supplies a power supply voltage to the heater 7 and flows a current to the heater 7 to heat the heater 7. The internal configuration of the heater driving unit 8 will be described later.

The exhaust mechanism 10 exhausts the reacted source gas from the inside of the chamber 2 via the gas discharge unit 9 and controls a pressure in the chamber 2 to a desired pressure by an action of an exhaust valve 10a and a vacuum pump 10b.

The radiation thermometer 11 is provided on an upper surface of the raw material discharge unit 4. The radiation thermometer 11 irradiates the wafer W with light beam from a light source which is not shown, receives reflected light beam from the wafer W, and measures a reflected light beam intensity of the wafer W. In addition, the radiation thermometer 11 receives thermal radiation light from a film growth surface of the wafer W and measures a thermal radiation light intensity. One radiation thermometer 11 is illustrated in FIG. 1. However, the plurality of radiation thermometers 11 may be arranged on the upper surface of the raw material discharge unit 4 to measure temperatures of positions on the film growth surface of the wafer W (for example, inner peripheral side and outer peripheral side).

A light transmitting window is provided in the upper surface of the raw material discharge unit 4, and the light beam from the light source of the radiation thermometer 11 and the reflected light beam and the thermal radiation light from the wafer W pass through the light transmitting window. The light transmitting window may have any shapes such as a slit shape, a rectangular shape, and a circular shape. A transparent member regarding a wavelength range of light beam to be measured by the radiation thermometer 11 is used to form the light transmitting window. In a case where a temperature of a room temperature to about 1500° C. is measured, it is preferable to measure a wavelength of light beam in a visible range to light beam in a near-infrared range. In such a case, quartz and the like are preferably used as the member of the light transmitting window.

The controller 12 includes a computer (not shown) which intensively controls the vapor phase growth apparatus 1 and a storage unit (not shown) for storing a process control program, a device history, and the like. The controller 12 controls the gas supply unit 3, a rotation mechanism of the rotation unit 6, the exhaust mechanism 10, heating of the wafer W by the heater 7, and the like.

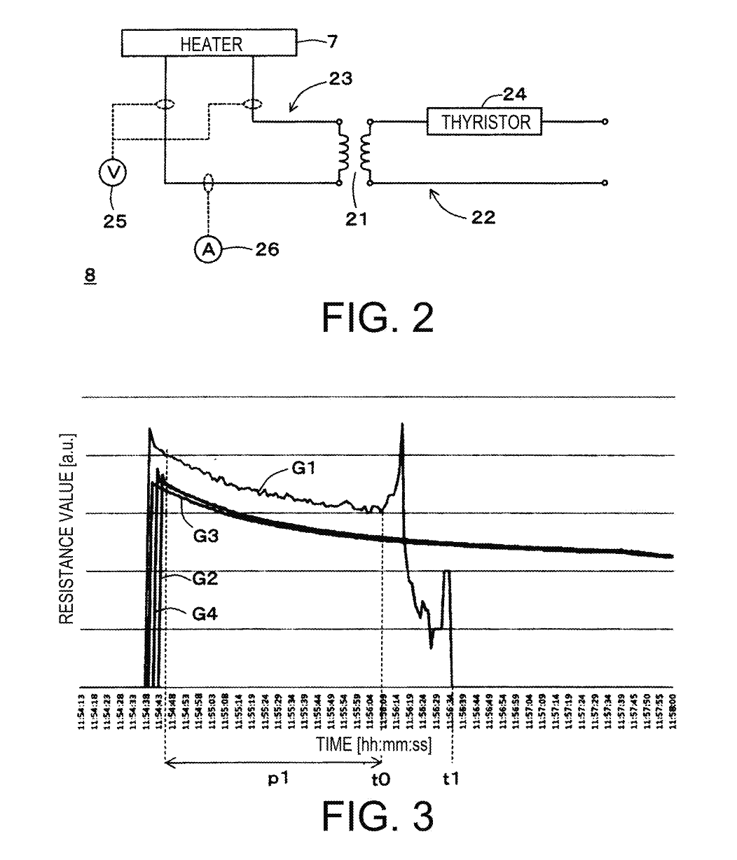

FIG. 2 is a circuit configuration diagram illustrating an exemplary internal configuration of the heater driving unit 8. The heater driving unit 8 in FIG. 2 includes a transformer 21, a primary circuit 22 connected to the primary side of the transformer 21, and a secondary circuit 23 connected to the secondary side of the transformer 21. The primary circuit 22 includes a thyristor 24, and a commercial power supply voltage, for example, is applied to the primary circuit 22. The transformer 21 performs voltage conversion between an AC voltage on the primary circuit 22 side and an AC voltage on the secondary circuit 23 side. The heater 7 is connected to the secondary circuit 23. A voltmeter 25 and an ammeter 26 are connected to the secondary circuit 23. The voltmeter 25 measures a voltage to be applied to the heater 7, and the ammeter 26 measures a current flowing through the heater 7. The measured values of the voltmeter 25 and the ammeter 26 are supplied to the controller 12.

When operating the plurality of vapor phase growth apparatuses 1 having similar configuration to that in FIG. 1 in parallel, it has been found that timings of breakage of the heaters 7 of the vapor phase growth apparatuses 1 are different from each other and a sign of the breakage appears in the electrical characteristics of the heater 7 before the heater 7 is completely broken.

FIG. 3 is a graph illustrating the electrical characteristics of each heater 7 in each of four vapor phase growth apparatuses 1. A graph G1 in FIG. 3 indicates the electrical characteristics of the heater 7 which has been completely broken, and graphs G2 to G4 indicate the electrical characteristics of the heaters 7 which have not been broken. The horizontal axis of the graphs G1 to G4 indicates time [hour, minute, second] and the vertical axis indicates a resistance value [a.u.].

In the graph G1, the resistance value fluctuates in a short cycle within a period p1 before time t1. It is considered that the heater 7 is completely broken at time t1. After that, from time t0 to time t1, the resistance value fluctuates with a larger amplitude in a longer cycle than that in the period p1. It is considered that breakage is considerably progressed after time t0. In some cases, scattering of a part of the component materials of the heater 7 into the chamber 2 may be started. Therefore, if it is possible to find the period of the slight and quick fluctuations in the period p1 before time t0, the heater 7 can be exchanged before the component materials of the heater 7 scatter in the chamber 2.

As illustrated in FIG. 3, after the period p1, the resistance value of the heater 7 largely fluctuates, and after that, the heater 7 is completely broken. Regarding each of the graphs G2 to G4 in FIG. 3, the resistance value of the heater 7 gradually decreases. However, if the resistance value of the heater 7 is measured in a longer period, the longer the use period of the heater 7 is, the more the resistance value of the heater 7 increases. In the present embodiment, the resistance values are measured at multiple times at time intervals corresponding to the cycle in which the resistance value of the heater 7 slightly and quickly fluctuates in the period p1, and the breakage of the heater 7 is predicted in advance.

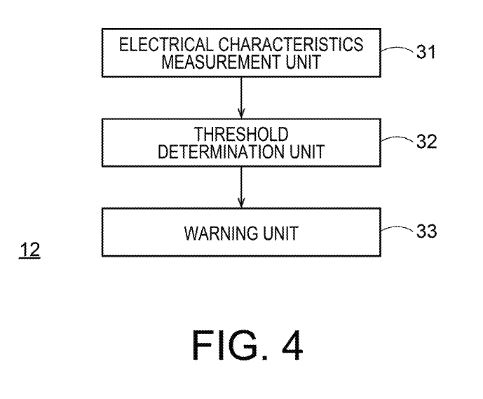

FIG. 4 is a block diagram illustrating an exemplary internal configuration of the controller 12. The controller 12 in FIG. 4 includes an electrical characteristics measurement unit 31, a threshold determination unit 32, and a warning unit 33.

The electrical characteristics measurement unit 31 measures the electrical characteristics of the heater 7 at predetermined time intervals and detects a variation value of the electrical characteristics. The threshold determination unit 32 determines whether a difference between the maximum value and the minimum value of the predetermined number of detected variation values of the electrical characteristics exceeds a predetermined threshold. The warning unit 33 performs warning processing in a case where it has been determined that the difference has exceeded the threshold.

Here, the electrical characteristics is at least one of the voltage to be applied to the heater 7, the current flowing through the heater 7, and the resistance value of the heater 7. In the following description, an example will be described in which the electrical characteristics measurement unit 31 measures the resistance value of the heater 7 multiple times at predetermined time intervals. Here, the predetermined time is a time interval corresponding to the slight and quick fluctuation cycle of the resistance value of the heater 7 in the period p1 in FIG. 3.

In a case where the electric characteristic is the resistance value, the electrical characteristics measurement unit 31 detects a variation value from the resistance value, which has been measured at the previous time, each time when the resistance value is measured. The threshold determination unit 32 determines whether a difference between the maximum value and the minimum value of the variation values of multiple times exceeds a threshold.

The warning unit 33 performs the warning processing by using, for example, an alarm sound source and a display device (not shown) connected to the controller 12. For example, the alarm sound source sounds and notifies that the timing of breakage of the heater 7 comes soon by the sound. Alternatively, a display indicating that the timing of breakage of the heater 7 comes soon is displayed on the display device.

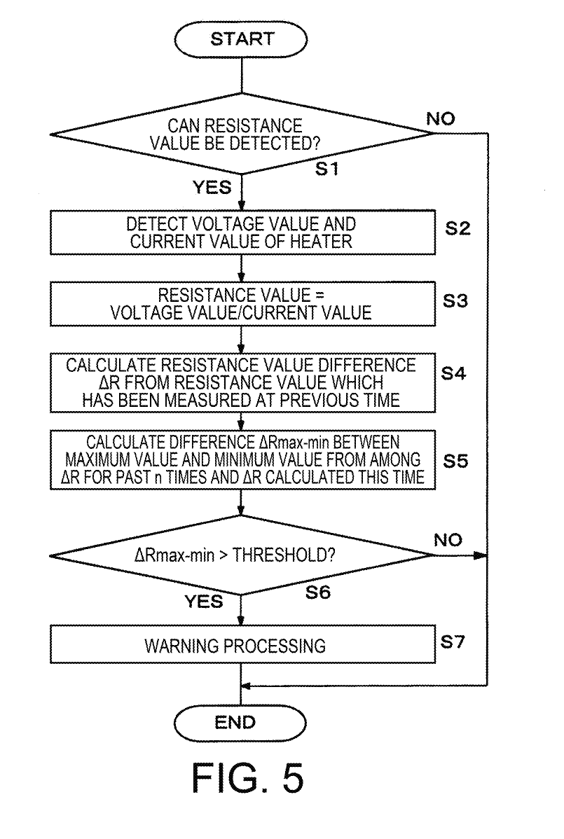

FIG. 5 is a flowchart illustrating an exemplary processing operation of the controller 12. The flowchart illustrates abnormality detection processing of the heater 7 performed by the controller 12. The controller 12 may perform various processing other than this processing. However, other processing is omitted in FIG. 5. The controller 12 performs the processing in FIG. 5 at predetermined time intervals.

First, it is determined whether the resistance value of the heater 7 can be detected (step S1). For example, if it is determined that the resistance value of the heater 7 cannot be normally detected due to some reason, the results of the determination processing in step S1 is NO, and the processing in FIG. 5 is terminated.

If the result in step S1 is YES, the electrical characteristics measurement unit 31 measures a current value and a voltage value of the heater 7 by using the voltmeter 25 and the ammeter 26 in FIG. 2 (step S2). Next, the electrical characteristics measurement unit 31 calculates the resistance value=the voltage value/the current value (step S3).

Next, the electrical characteristics measurement unit 31 calculates a resistance value difference (variation value) ΔR from the resistance value which has been measured at the previous time (step S4). When there is no resistance value which has been measured at the previous time, the processing in step S4 is omitted.

Next, the electrical characteristics measurement unit 31 detects a difference ΔRmax−min between the maximum value and the minimum value from among resistance value differences ΔR for the past n (for example, four) times and a resistance value difference ΔR calculated this time (step S5).

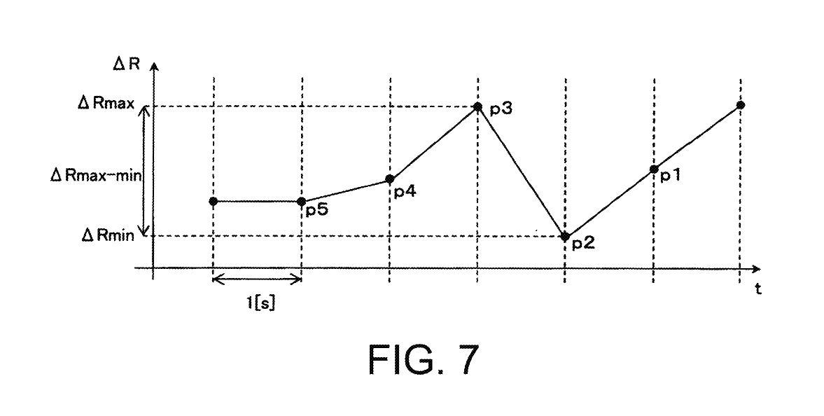

FIG. 7 is a graph illustrating an exemplary calculation result of resistance value differences which have been calculated for four times in the past and calculated this time. The horizontal axis indicates time, and the vertical axis indicates a resistance value difference. A fifth plot p1 in FIG. 7 is the resistance value difference of this time, and plots p2 to p5 are the resistance value differences of four times in the past. In a case of FIG. 7, a difference between the resistance value difference of the plot p2 and the resistance value difference of the plot p3 is ΔRmax−min.

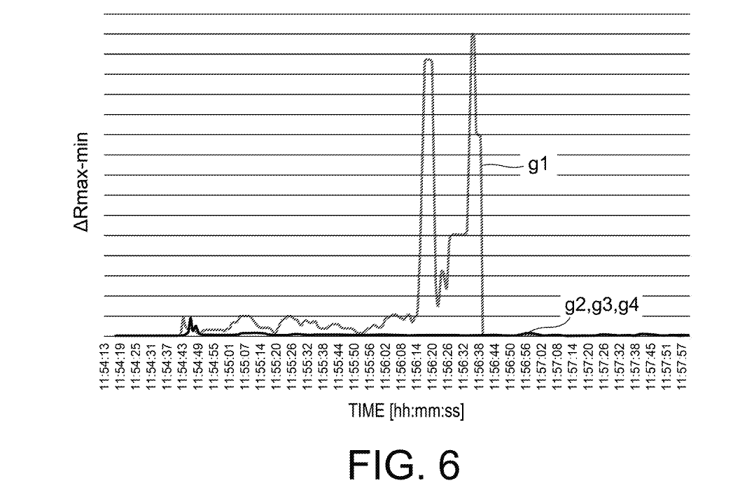

The processing in step S5 is provided so as to surely detect the fluctuation in the resistance value of the heater 7 before the heater 7 is completely broken. For example, in a case where changes in the resistance values of the four heaters 7 are respectively indicated by the graphs G1 to G4 in FIG. 3, graphs g1 to g4 after the processing in step S5 are as illustrated in FIG. 6. The horizontal axis in FIG. 6 indicates time [hour, minute, second] and, the vertical axis indicates a difference ΔRmax−min between the maximum value and the minimum value of the resistance value differences. The graphs g1 to g4 in FIG. 6 respectively correspond to the graphs G1 to G4 in FIG. 3. The graph g1 in FIG. 3 corresponds to the broken heater 7, and the difference ΔRmax−min largely changes before the heater 7 is completely broken. Therefore, the slight and quick fluctuations before the heater 7 is completely broken can be surely detected.

When the difference ΔRmax−min is detected in step S5 in FIG. 5, the threshold determination unit 32 subsequently determines whether the difference ΔRmax−min exceeds a predetermined threshold (step S6). In a case where the difference exceeds the threshold, the warning unit 33 performs predetermined warning processing (step S7). In a case where the difference does not exceed the threshold, the processing in FIG. 5 is terminated.

As described above, in the first embodiment, the resistance value of the heater 7 is measured at predetermined time intervals, a variation value between the newly measured resistance value and the previous resistance value is detected, and it is determined whether the difference between the maximum value and the minimum value from among the plurality of variation values exceeds the threshold. As a result, the slight and quick change in the resistance value of the heater 7 before the heater 7 is completely broken can be accurately detected. Therefore, the sign of the breakage of the heater 7 can be found, and the heater 7 can be exchanged immediately before the heater 7 is broken. Therefore, a disadvantage that the component materials of the heater 7 scatter in the chamber 2 can be prevented.

### Second Embodiment

In the first embodiment described above, the example has been described in which the single threshold used to determine the breakage of the heater 7 is provided. However, stepwise warning processing may be performed by providing a plurality of thresholds.

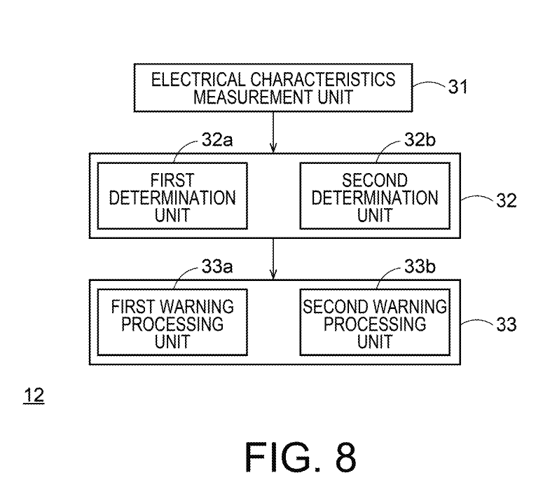

FIG. 8 is a flowchart illustrating an internal configuration of a controller 12 according to a second embodiment. In the controller 12 in FIG. 8, a first determination unit 32a and a second determination unit 32b are provided in a threshold determination unit 32. In a warning unit 33, a first warning processing unit 33a and a second warning processing unit 33b are provided.

The first determination unit 32a determines whether a difference ΔRmax−min described above exceeds a first threshold. After the first determination unit 32a has determined that the difference has exceeded the first threshold, the second determination unit 32b determines whether the difference ΔRmax−min exceeds a second threshold which is larger than the first threshold.

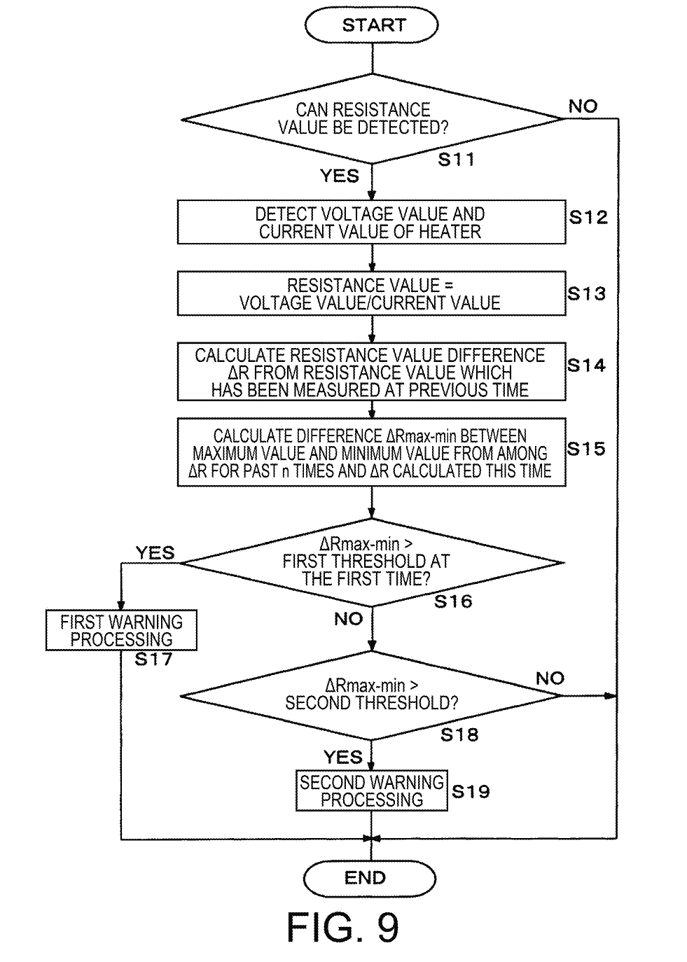

FIG. 9 is a flowchart illustrating an exemplary processing operation of the controller 12. Processing in steps S11 to S15 is the same as the processing in steps S1 to S5 in FIG. 5. The controller 12 performs the processing in FIG. 9 at predetermined time intervals.

When the difference ΔRmax−min is detected in step S15, the first determination unit 32a determines whether the difference ΔRmax−min has exceeded the first threshold for the first time (step S16). When it is determined that the difference has exceeded the first threshold, the first warning processing unit 33a performs first warning processing (step S17).

In a case where the result of the determination in step S16 is NO, the second determination unit 32b determines whether the difference ΔRmax−min exceeds the second threshold which is larger than the first threshold (step S18). When it is determined that the difference has exceeded the second threshold, the second warning processing unit 33b performs second warning processing (step S19).

Various specific processing contents of the first warning processing and the second warning processing can be considered. For example, between the first warning processing and the second warning processing, a sounding method of the alarm sound source or a display content of the display device may be changed. More specifically, in the second warning processing, it is considered that the sounding method or the display to notify that the breakage of the heater 7 comes sooner is made. Alternatively, in the first warning processing, the alarm sound source or the display device may notify that the breakage of the heater 7 comes soon. In the second warning processing, in addition to the notification, stop processing for stopping power supply to the heater 7 may be performed to the heater driving unit 8.

For example, the first threshold is set to detect the period p1 in FIG. 3, and the second threshold is set to detect the times t0 to t1 in FIG. 3. If the result of the determination in step S18 is NO, the processing returns to step S11.

In step S19 described above, when the difference ΔRmax−min exceeds the second threshold, in addition to the warning processing, power supply to the heater 7 may be stopped. Alternatively, warning processing different from that in step S17 may be performed.

As described above, in the second embodiment, the resistance value of the heater 7 is measured at predetermined time intervals, a variation value between the newly measured resistance value and the previous resistance value is detected. Furthermore, since the first threshold and the second threshold are provided as thresholds to determine the difference ΔRmax−min between the minimum value and the minimum from among the variation values for the plurality of times, it is possible to notify that the breakage of the heater 7 comes soon in detail by two kinds of warning processing.

In the first embodiment and the second embodiment described above, the processing of comparing the difference ΔRmax−min of the resistance value of the heater 7 with the threshold is performed. However, the current flowing through the heater 7 may be compared with the threshold.

In the first embodiment and the second embodiment described above, the abnormality detection method of detecting breakage of the heater 7 in the vapor phase growth apparatus 1 has been described. However, the heater 7 is not limited to a heater provided in the vapor phase growth apparatus 1.

Several embodiments of the present invention have been described. These embodiments have been presented as an example and are not intended to limit the scope of the invention. These novel embodiments can be implemented in various other forms, and various omissions, replacements, and changes can be made without departing from the gist of the invention. These embodiments and modifications thereof are included in the scope and gist of the invention, and are included in the invention described in the claims and the equivalent scope thereof.

1. A vapor phase growth apparatus comprising:
a reaction chamber to form a film on an upper surface of a substrate by a vapor growth reaction;
a gas supplier to supply a gas to the reaction chamber;
a heater to heat the substrate from a back side of the substrate; and
a controller to control an output of the heater, wherein
the controller comprises:
an electrical characteristics measuring instrument which measures electrical characteristics of the heater at predetermined time intervals and detects a variation value of the electrical characteristics between a newly value and previous value; and
a threshold determiner which extracts a maximum value and a minimum value of a predetermined number of detected variation values and newly variation value of the electrical characteristics, calculates differences between the maximum value and the minimum value at the predetermined time intervals, and determines whether the difference exceeds a predetermined threshold.

2. The vapor phase growth apparatus according to claim 1, further comprising an alarm to perform warning processing in a case where the threshold determiner has determined that the difference has exceeded the predetermined threshold.

3. The vapor phase growth apparatus according to claim 1, wherein the electrical characteristics is at least one of a voltage to be applied to the heater, a current flowing through the heater, and a resistance value of the heater.

4. The vapor phase growth apparatus according to claim 1, wherein the electrical characteristics measuring instrument detects a variation value from a resistance value previously measured each time when measuring the resistance value of the heater.

5. The vapor phase growth apparatus according to claim 1, wherein the threshold determiner determines whether a difference between a maximum value and a minimum value of a predetermined number of variation values which have been detected in the past exceeds the threshold.

6. The vapor phase growth apparatus according to claim 2, wherein
the threshold determiner comprises:
a first determiner which determines whether a difference between a maximum value and a minimum value of the variation values of the electrical characteristics exceeds a first threshold; and
a second determiner which determines whether the difference between the maximum value and the minimum value of the variation values of the electrical characteristics exceeds a second threshold which is larger than the first threshold after the first determiner has determined that the difference has exceeded the first threshold, and
the alarm comprises:
a first alarm which performs first warning processing when the first determination unit has determined that the difference has exceeded the first threshold; and
a second alarm which performs second warning processing when the second determiner has determined that the difference has exceeded the second threshold.

7. The vapor phase growth apparatus according to claim 6, wherein the first warning processor performs the first warning processing when the first determination unit has determined that the difference has exceeded the first threshold at the first time.

8. The vapor phase growth apparatus according to claim 6, wherein after the second warning processing, heating stop processing is performed on the heater.

9. The vapor phase growth apparatus according to claim 1, wherein the predetermined time is a time interval according to a fluctuation cycle of the electrical characteristics of the heater before the heater is broken.

10. An abnormality detection method of a heater for heating a substrate placed in a reaction chamber, the method comprising:
measuring a resistance value of the heater at predetermined time intervals;
detecting a variation value of the measured resistance values; and
determining whether a difference between a maximum value and a minimum value of the predetermined number of detected variation values exceeds the threshold.

11. The abnormality detection method according to claim 10, wherein warning processing is performed in a case where it has been determined that the difference has exceeded the threshold.

12. The abnormality detection method according to claim 10, wherein the electrical characteristics is at least one of a voltage to be applied to the heater, a current flowing through the heater, and a resistance value of the heater.

13. The abnormality detection method according to claim 10, wherein a variation value from a resistance value previously measured is detected each time when the resistance value of the heater is measured.

14. The abnormality detection method according to claim 11, wherein whether a difference between a maximum value and a minimum value of the predetermined number of variation values detected in the past exceeds the threshold is determined.

15. The abnormality detection method according to claim 10, comprising:
determining whether the difference between the maximum value and the minimum value of the variation values of the electrical characteristics exceeds a first threshold; and
determining whether the difference between the maximum value and the minimum value of the variation values of the electrical characteristics exceeds a second threshold which is larger than the first threshold after it has been determined that the difference has exceeded the first threshold.

16. The abnormality detection method according to claim 10, comprising:
performing first warning processing when it has been determined that the difference has exceeded the first threshold; and
performing second warning processing when it has been determined that the difference has exceeded the second threshold.

17. The abnormality detection method according to claim 16, wherein the first warning processing is performed in a case where it has been determined that the difference has exceeded the first threshold at the first time.

18. The abnormality detection method according to claim 16, wherein after the second warning processing, heating stop processing is performed on the heater.

19. The abnormality detection method according to claim 10, wherein the predetermined time is a time interval according to a fluctuation cycle of the electrical characteristics of the heater before the heater is broken.
